(19) United States
(12) Patent Application Publication
(10) Pub. No.: US 2008/0093702 A1
(43) Pub. Date: Apr. 24, 2008

(54) SEMICONDUCTOR DEVICE HAVING A PASSIVE DEVICE

(75) Inventors: Hung-Hsiang Cheng, Kaohsiung (TW); Sung-Mao Wu, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 11/848,251

(22) Filed: Aug. 31, 2007

(30) Foreign Application Priority Data
Oct. 23, 2006 (TW) 095139023

(51) Int. Cl. H01L 29/00

(52) U.S. Cl. 257/528; 257/E29.001

(57) ABSTRACT

The present invention relates to a semiconductor device having a passive device. The semiconductor device includes a substrate and at least one passive device. The substrate has at least one via. The via has at least two conductive elements therein. The conductive elements are not electrically connected to each other. The passive device has at least two electrodes, and is disposed on the substrate. The electrodes are electrically connected to the conductive elements respectively. The passive device needs only one via, so the amount of vias can be reduced effectively. In addition, the conductive path formed by the conductive elements and the passive device is relatively short, so that the inductance is lowered and the electrical performance is raised.

### BACKGROUND OF THE INVENTION

1. Field of the Invention

The present invention relates to a semiconductor device, and more particularly to a semiconductor device having a passive device.

2. Description of the Related Art

To meet current demands for high circuit density, a substrate is designed for a multi-layered structure. Further, in order to electrically connect the layers to the circuit on the surface of the substrate, a plurality of vias are additionally disposed in the substrate. Additionally, in practical applications, a plurality of passive devices are usually disposed in the circuit on the surface of the substrate.

FIG. 1 shows a schematic view of a conventional semiconductor device having a passive device. The conventional semiconductor device 1 includes a substrate 11 and a passive device 12. The substrate 11 has an upper surface 111, a lower surface, a first via 113, a second via 114, a first conductive trace 115, a second conductive trace 116, a first pad 117, a second pad 118, and a plurality of dielectric layers 119. The first via 113 opens to the first upper surface 111, and is filled with a first conductive element 13. The first conductive element 13 is connected to a ground layer 15. The second via 114 opens to the first upper surface 111, and is filled with a second conductive element 14. The second conductive element 14 is connected to a power layer 16. The ground layer 15 and the power layer 16 are completely distributed or partially distributed between two dielectric layers 119, respectively.

The first conductive trace 115, the second conductive trace 116, the first pad 117, and the second pad 118 are located on the upper surface 111 of the substrate 11. The first conductive trace 115 is used to connect the first pad 117 and the first conductive element 13. The second conductive trace 116 is used to connect the second pad 118 and the second conductive element 14.

The passive device 12 (for example, a capacitor, a resistor, or an inductor) has a first end electrode 121 and a second end electrode 122. The passive device 12 is disposed on the upper surface 111 of the substrate 11. The first end electrode 121 contacts the first pad 117 and is electrically connected to the ground layer 15 through the first conductive element 13. The second end electrode 122 contacts the second pad 118 and is electrically connected to the power layer 16 through the second conductive element 14.

The conventional semiconductor device 1 has the disadvantage that the passive device 12 must be connected to two vias (the first via 113 and the second via 114). When a large number of passive devices 12 are to be disposed on the substrate 11, the amount of vias is greatly increased, thus taking up a large space. As a result, the number of the passive devices 12 is restricted and must be reduced. In addition, the conductive path formed by the first conductive element 13, the first conductive trace 115, the passive device 12, the second conductive trace 116, and the second conductive element 14 is relatively large, so the inductance is large and the electrical performance is reduced.

Therefore, it is necessary to provide a semiconductor device having a passive device to solve the above problems.

### SUMMARY OF THE INVENTION

The objective of the invention is to provide a semiconductor device having a passive device. The semiconductor device includes a substrate and at least one passive device. The substrate has at least one via. The via includes at least two conductive elements. The conductive elements are not electrically connected to each other. The passive device has at least two electrodes, and is disposed on the substrate. The electrodes are electrically connected to the conductive elements respectively. In the semiconductor device, the passive device needs only one via, so the amount of vias will not be greatly increased when the number of the passive devices increases. Further, the via is located right below the passive device and does not take up additional space, and thus more passive devices can be disposed on the substrate. In addition, the conductive path formed by the first conductive element, the passive device, and the second conductive element is relatively short, so that the inductance is lowered and the electrical performance is raised.

### BRIEF DESCRIPTION OF THE DRAWINGS

FIG. 1 shows a schematic view of a conventional semiconductor device having a passive device;

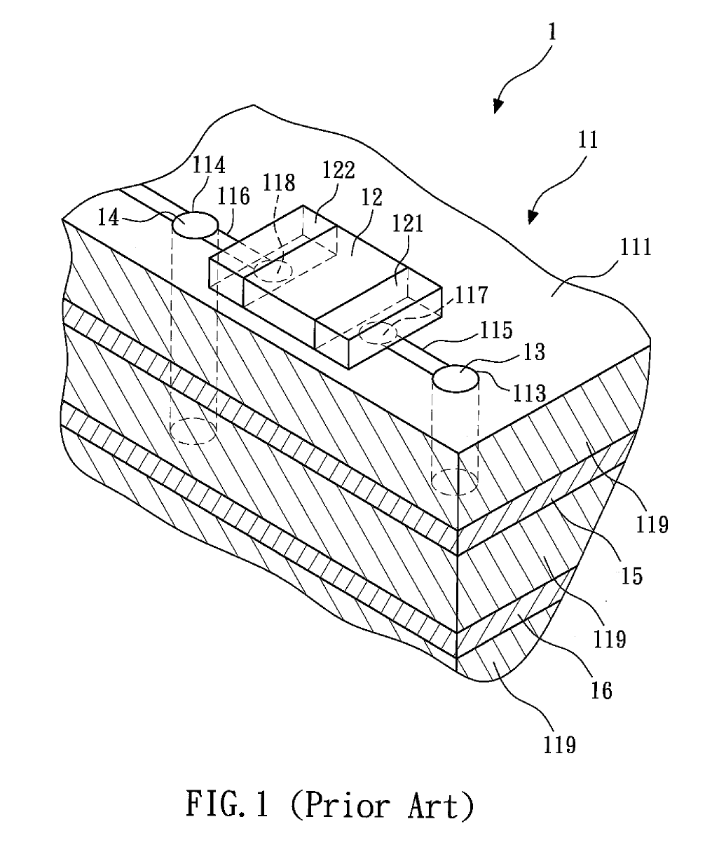

FIG. 2 shows a schematic exploded view of a semiconductor device having a passive device according to the present invention; and

FIG. 3 shows a schematic assembly view of a semiconductor device having a passive device according to the present invention.

### DETAILED DESCRIPTION OF THE INVENTION

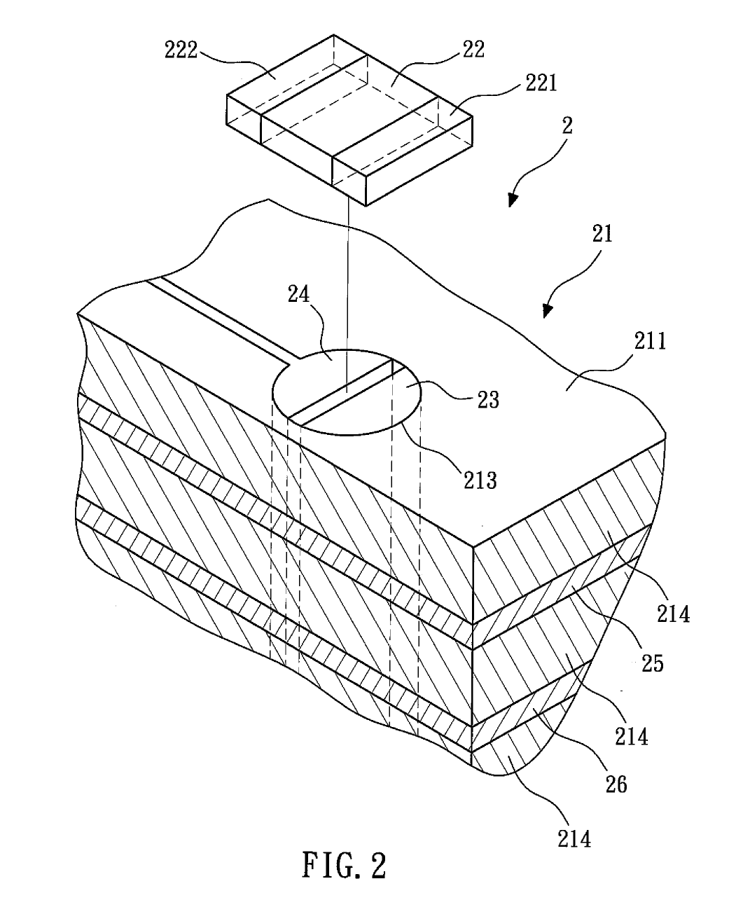

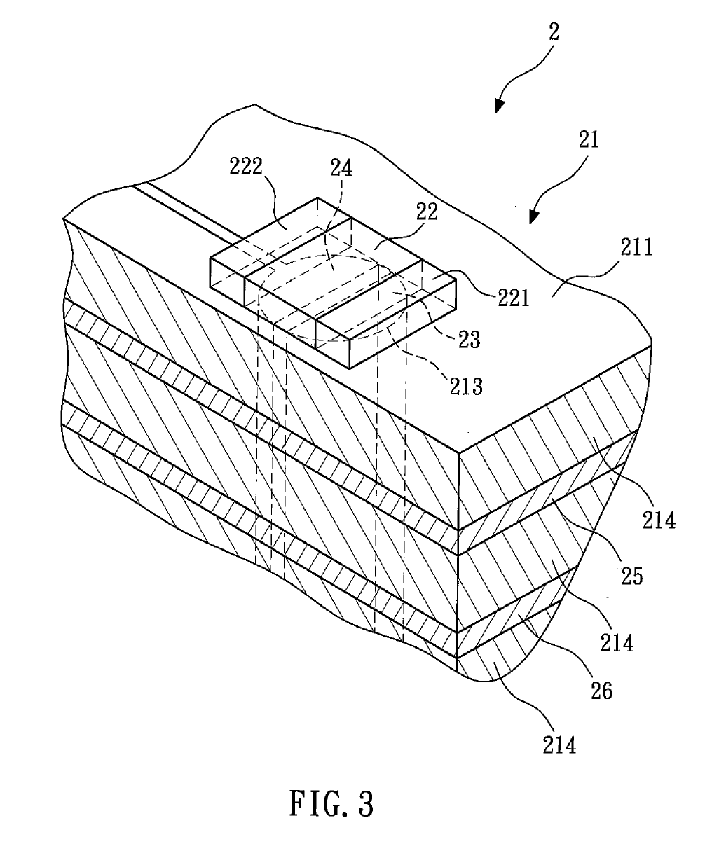

FIGS. 2 and 3 show a schematic exploded view and a schematic assembly view of a semiconductor device having a passive device according to the present invention, respectively. The semiconductor device 2 includes a substrate 21 and at least one passive device 22. The substrate 21 has an upper surface 211, a lower surface (not shown), a via 213, a ground layer 25, a power layer 26, and a plurality of dielectric layers 214. The via 213 opens to the first upper surface 211, and has at least two conductive elements therein. The conductive elements are exposed outside the first upper surface 211, and are not electrically connected to each other. The via 213 can be a blind hole or through hole. The ground layer 25 and the power layer 26 are completely distributed or partially distributed between two dielectric layers 214, respectively.

In this embodiment, the via 213 has a first conductive element 23 and a second conductive element 24 therein. The first conductive element 23 and the second conductive element 24 are separated and not electrically connected to each other, and are formed by, for example, filling a conductive element (for example, metal) in the via 213, and then cutting the conductive element into two halves by means of laser sawing. Moreover, the separated first conductive element 23 and second conductive element 24 can be formed by another method. In this embodiment, the first conductive element 23 and the second conductive element 24 are semicircular, and have substantially the same areas. However, it is understood that the first conductive element 23 and the second conductive element 24 can be in another configuration. In this embodiment, the first conductive element 23 is electrically connected to the ground layer 25 and is electrically insulated from the power layer 26. The second conductive element 24 is electrically connected to the power layer 26 and electrically insulated from the ground layer 25. That is, the first conductive element 23 and the second conductive element 24 are respectively connected to different electric potentials. However, it is understood that the first conductive element 23 and the second conductive element 24 can be connected to the same electric potential.

The passive device 22 (for example, a capacitor with a 0402 or 0201 model, a resistor, or an inductor) has a first end electrode 221 and a second end electrode 222. The passive device 22 is disposed on the upper surface 211 of the substrate 21, and the first end electrode 221 and the second end electrode 222 are electrically connected to the first conductive element 23 and the second conductive element 24, respectively. In this embodiment, the first end electrode 221 directly contacts the first conductive element 23 and is electrically connected to the ground layer 25. The second end electrode 222 directly contacts the second conductive element 24 and is electrically connected to the power layer 26.

In other applications, if the size of the via 213 is smaller than that of the passive device 22, so the first end electrode 221 and the second end electrode 222 cannot directly contact the first conductive element 23 and the second conductive element 24, a first conductive trace and a second conductive trace can be added to the upper surface 211 of the substrate 21. The first conductive trace is used to connect the first end electrode 221 and the first conductive element 23, and the second conductive trace is used to connect the second end electrode 222 and the second conductive element 24.

In another embodiment, the via 213 penetrates the substrate 21, so that the first conductive element 23 and the second conductive element 24 are further exposed outside the lower surface of the substrate 21. Moreover, if another passive device is disposed on the lower surface of the substrate 21, the first conductive element 23 and the second conductive element 24 can be connected by the above-mentioned method.

The present invention has the following advantages. In the semiconductor device 2, the passive device 22 needs only one via (the via 213), so the amount of vias 213 will not be greatly increased when the number of the passive device 22 increases. Further, the via 213 is located right below the passive device 22 and does not take up additional space, and thus more passive devices 22 can be disposed on the substrate 21. In addition, the conductive path formed by the first conductive element 23, the passive device 22, and the second conductive element 24 is relatively short, so that the inductance is lowered and the electrical performance is raised.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A semiconductor device having a passive device, comprising:
a substrate, having at least one via, the via having at least two conductive elements therein, and the conductive elements being not electrically connected to each other; and
at least one passive device, having at least two electrodes, the passive device being disposed on the substrate, and the electrodes being electrically connected to the conductive elements respectively.

2. The semiconductor device as claimed in claim 1, wherein the conductive elements are formed by laser sawing.

3. The semiconductor device as claimed in claim 1, wherein the substrate has an upper surface, the conductive elements are exposed outside the upper surface of the substrate, and the passive device is disposed on the upper surface of the substrate.

4. The semiconductor device as claimed in claim 3, wherein the substrate further has a lower surface, and the via penetrates the substrate, so that the conductive elements are further exposed outside the lower surface of the substrate, and another passive device is disposed on the lower surface of the substrate.

5. The semiconductor device as claimed in claim 1, wherein the conductive elements comprise a first conductive element and a second conductive element, the first conductive element is electrically connected to a ground layer, and the second conductive element is electrically connected to a power layer.

6. The semiconductor device as claimed in claim 1, wherein the passive device is a capacitor, a resistor, or an inductor.

7. The semiconductor device as claimed in claim 6, wherein the electrodes are end electrodes.

8. The semiconductor device as claimed in claim 1, wherein the substrate further comprises a plurality of conductive traces, for connecting the electrodes and the conductive elements.

9. The semiconductor device as claimed in claim 1, wherein the electrodes directly contact the conductive elements.

10. The semiconductor device as claimed in claim 1, wherein the passive device is disposed above the conductive elements.

11. The semiconductor device as claimed in claim 1, wherein the conductive elements are respectively connected to different electric potentials.
